(19) United States
(12) Patent Application Publication
(10) Pub. No.: US 2009/0253227 A1
(43) Pub. Date: Oct. 8, 2009

(54) ENGINEERED OR STRUCTURED COATINGS FOR LIGHT MANIPULATION IN SOLAR CELLS AND OTHER MATERIALS

(76) Inventors: Anthony Defries, Los Angeles, CA (US); Mark Brongersma, Redwood City, CA (US)

Correspondence Address: MATTER, INC., 149 S. BARRINGTON AVE #757, LOS ANGELES, CA, 90049, US

(21) Appl. No.: 12/416,866

(22) Filed: Apr. 1, 2009

Related U.S. Application Data
(60) Provisional application No. 61/043,281, filed on Apr. 8, 2008.

(51) Int. Cl. H01L 21/00

(52) U.S. Cl. 438/72; 257/E21.002

(57) ABSTRACT

The present disclosure concerns a means to design, engineer and use antireflective or metallo-dielectric coatings incorporating metallic, nonmetallic, organic and inorganic metamaterials or nanostructures to manipulate light in solar thermal and photovoltaic materials. Such metallic, nonmetallic, organic or inorganic metamaterials or nanostructures could be used to manipulate light for photovoltaic effects on or in any material or substrate. Dielectric coatings containing metallic nanostructures could be used to improve the efficiency of solar cells and to influence or control such characteristics as optical and thermal absorption, conduction, radiation, emissivity, reflectivity and scattering.

### CROSS REFERENCE TO RELATED APPLICATIONS

This application claims benefit of and priority to U.S. Provisional Patent Application No. 61/043,281 filed Apr. 8, 2008 entitled “Light Manipulation in Engineered or Structured Coatings for Solar Thermal and Photovoltaic Materials” which application is incorporated herein by reference in its entirety.

### BACKGROUND

1. Field

The present disclosure concerns a means to design, engineer and use antireflective or dielectric coatings incorporating metallic, nonmetallic, organic and inorganic metamaterials or nanostructures to manipulate light in solar thermal and photovoltaic materials and device structures. The invention described herein provides that such metallic, nonmetallic, organic or inorganic metamaterials or nanostructures could be used to manipulate light to enhance photovoltaic effects on or in any material, device or substrate. The invention further provides that dielectric coatings containing metallic nanostructures could be used to improve the efficiency of solar cells and to influence or control such characteristics as optical absorption, thermal transport and emission, light concentration, subwavelength light manipulation, impedance matching, electrical conductivity, emissivity, reflectivity and scattering. The present disclosure further concerns the use or application of such coatings or structures for control of light-matter interactions or enhancement of photovoltaic effects through the management of reflective or refractive properties. The invention is also addressed to methods of coating various substrates including semiconductor or other materials used for or in the production of photovoltaic or thermal solar cells.

2. Related Art

Metallic nanostructures exhibit strong light-matter interactions that enable them to induce light absorption in other materials with unparalleled spatial and temporal control. Such interactions with engineered metallic nanostructures can enable various effects including light concentration in a pn-junction or desired layer of a solar cell scattering of light into waveguide modes, local field enhancement, and phase matching, photon coupling and recoupling, high optical transmission electrical contacts and thermal radiation engineering. Different solar cells present unique engineering challenges to attain high efficiency or reduce materials use and cost. The development of advanced optical structures has enabled tremendous control over the propagation and manipulation of light waves. Many important technologies and applications utilize this control including optical microscopy, solar cells, solid-state devices, light sources, biotechnology, medicine and communications. It was a generally held belief until recently that manipulation of light was limited to a relatively large wavelength scale of about 1 μm by the fundamental laws of diffraction. Plasmonics is an exploding new field of science in which the flow of light can be controlled at the nanoscale below the diffraction limit by using metallic nanostructures. This is rapidly impacting every facet of optics and photonics while enabling a myriad of new technologies.

A typical photovoltaic solar cell involves the following operation; photon absorption and carrier generation charge carrier separation, and carrier collection. Each step has associated losses that compound to limit efficiency. Major loss occurs during photon absorption. The entire solar spectrum consists of many different wavelengths. Photon absorption for electron excitation is wavelength dependent. Current photovoltaic solar cells typically capture less than 30% of direct or incident photons because they are not optimized to utilize the entire solar spectrum. Increasing spectrum utilization or the number of electrons stimulated per photon could increase overall efficiency of solar cells. Further progress will require the development of higher quality materials with smaller energy gaps and reduced energy loss. For example, photovoltaic cells in which the active layer is a composite of an organic material and semi-nanoparticles have shown promise for achieving lower energy gaps. The invention described herein provides a means to capture and utilize a larger portion of the entire solar spectrum and to maximize energy efficiency.

It has been established that metallic antenna nanostructures enable strong field concentration by means of impedance matching freely propagating light waves to local antenna modes. An important aspect of the invention described herein concerns the means to capture and concentrate the maximum light energy by the most efficient combination of nanostructured metallic, nonmetallic, organic, metalorganic or metamaterials materials. A feature of the invention described herein may include incorporating said materials in an antenna, receiver, collector or concentrating device for or as part of a photovoltaic, plasmonic or thermal solar cell material structure or design.

The use of anti-reflection (AR) coatings on solar cells is well established. Thin films of silica (SiO₂) and/or silicon nitride (Si₃N₄) are typically used to reduce the reflectivity of silicon solar cell allowing more photons to enter the active layer. Solar cells based on different materials (e.g. III-V semiconductors) or layer stacks employ anti-reflection coatings for the same purpose. For a single layer anti-reflection, the optimum index of the anti-reflection coating is given by the geometric mean of the two media surrounding the coating. For example, an anti-reflection coating on a substrate with index, n_{substrate}, would be given by: n_{AR}=\sqrt{n_{Air}n_{Substrate}}.

These simple single layer anti-reflection coatings have several drawbacks. The nature of an anti-reflection coating only reduces the reflectivity near a specific target wavelength, λ_{T}, and not the entire spectrum. In order to minimize the reflection at a specific λ_{T}, the index needs to be chosen as n_{AR} and the desired thickness will be λ_{T}/4n_{AR}. Multi-layer coatings can reduce the loss over a much larger part of the solar spectrum. Single layer coatings do not alter the direction of the light. Light that is normally incident to a solar cell will have a shorter interaction length with the absorbing medium compared to oblique rays. Therefore a cell thickness well exceeding the absorption depth of the semiconductor is needed to ensure absorption of all the photons. It has been suggested that Bragg gratings could be used to mitigate this problem. This is an expensive and limited solution since Bragg gratings only operate at specific wavelengths. A feature of the invention described herein may employ the unique optical properties of metallic nanostructures to enhance light scattering into oblique paths to increase absorption.

### BRIEF SUMMARY OF THE INVENTION

The present disclosure concerns a means to design, engineer and use antireflective or metallo-dielectric coatings incorporating metallic, nonmetallic, organic and inorganic metamaterials or nanostructures to manipulate light in solar thermal and photovoltaic materials and devices. Such metallic, nonmetallic, organic or inorganic metamaterials or nanostructures could be used to manipulate light for photovoltaic effects on or in any material, device, or substrate. Dielectric coatings containing metallic nanostructures could be used to improve the efficiency of solar cells and to influence or control such characteristics as optical and thermal absorption, conduction, radiation, emissivity, reflectivity and scattering.

### BRIEF DESCRIPTION OF THE DRAWINGS

Not Applicable

### DETAILED DESCRIPTION OF THE INVENTION

The present disclosure concerns a means to design, engineer or use antireflective or metallo-dielectric coatings incorporating metallic, nonmetallic, organic or inorganic metamaterials or nanostructures to manipulate light in solar thermal and photovoltaic materials. The invention described herein provides that such metallic, nonmetallic, organic or inorganic metamaterials or nanostructures could be used to manipulate light to enhance photovoltaic effects on or in any material, device, or substrate. The invention further provides that dielectric coatings containing metallic nanostructures could be used to improve the efficiency of solar cells and to influence or control such characteristics as optical absorption, thermal transport and emission, light concentration, subwavelength light manipulation, impedance matching, electrical conductivity, conduction, radiation, emissivity, reflectivity and scattering. The present disclosure further concerns the use or application of such coatings for control of light-matter interactions or enhancement of photovoltaic effects through the management of reflective or refractive properties. The invention is also addressed to methods of coating various substrates including semiconductor or other materials used for or in the production of photovoltaic or thermal solar cells. This invention concerns the engineering of coatings to control optical, photonic, plasmonic and photovoltaic effects. The use of dielectric and metallic nanostructures to generate superior light-management coatings can enable simultaneous anti-reflection, local field enhancement, light scattering in waveguides modes or coupling photons into paths that provide a longer interaction length with a desired absorbing layer. Such coatings can be utilized to improve the efficiency of existing solar cells. Metallic, organic, inorganic, nonmetallic, metalorganic, metamaterials, nanostructures, microstructures, nanopatterned structures or nanoengineered materials may be used as antennas or receivers to capture and redirect light energy from solar or other sources into to desired regions of a photovoltaic cell. The light can be separated by wavelengths using nanopatterned metallic structures or films. Photon scattering and manipulation by metallic nanostructures can be used to control light absorption by engineering the particle or cluster structure morphology, size, positioning within an array, composition or similar factors.

In an exemplary embodiment, transparent nanopatterned metallic structures or thin-film can be combined as contacts or electrodes to create photovoltaic subcells or multijunction stacks. These subcells or multifunction stacks can be spectrally or optically tuned. Absorption properties may be enhanced through the conductivity of transparent metal contacts. The resulting structures can be engineered to incorporate all the features and functions required to operate independently as a solar cell and may be deposited on or combined with any substrate.

In an exemplary embodiment metallo-dielectric coatings can boost the efficiency of solar harvesting devices (Photovoltaic and Thermal) in the following ways:
1) Coatings effectively reduce back-reflection of light over a broad wavelength range.
2) Coatings promote forward scattering of light into oblique directions that more strongly interact with the active medium (possibly waveguide modes in thin solar cells).
3) Coatings enable light concentration in those regions of the cell where light absorption most efficiently produces current, e.g. in the pn-junction or near a donor acceptor interface.
4) A cell or substrate (Photovoltaic or Thermal) coated with a metallo-dielectric coating. The layer consists of dielectric elements and metallic nanostructures. The total thickness and composition of the coating is optimized to reduce back-reflection of light over a broad wavelength range.
5) Subwavelength metallic nanostructures can enable local light concentration and scattering into oblique angles. In a thin device these may enable coupling into waveguide modes.

In an alternative embodiment, said layers may simply consist of dielectric films with a monolayer of metallic particles embedded in them. The particle shape, size, choice of metal, spacing between particles and distance to the substrate should be optimized to enable a specific goal, e.g. strong near-field enhancement or light scattering into oblique angles. The total thickness of the metallo-dielectric stack will be chosen to minimize back-reflection (AR or transparent conductive oxide (TCO) coating effect) and increase the coupling into the cell. Metals exhibiting strong plasmonic resonances may be advantageous for these types of coatings.

In a further embodiment coating designs may employ concepts and metamaterials comprised of deep subwavelength building blocks to enable the ultimate control over the flow of light. Metallo-dielectric coatings consisting of deep subwavelength metallic nanostructures in a dielectric matrix possess an effective index that can be locally engineered through a proper choice and placement of metallic inclusions. These metamaterial coatings can be designed to act as superior broadband anti-reflection coating as well as a light scattering and light concentration layers. These types of coatings can be engineered to produce a desired index variation above the cell by altering the metal fraction in the coating as a function of the distance from the substrate. They can be designed to act as a multilayer antireflective coating or so-called “moth eye” structure exhibiting a substantial reduction in light reflection over single layer antireflection coatings. A moth eye structure is highly non-reflective with orderly nanostructured surface variations to allow absorption rather than reflection of incoming light. Such coatings could generate higher cell efficiencies when compared to a cell with a multilayer dielectric anti-reflective coating due to enhanced light concentration and scattering effects. The operation of a metamaterials coating does not rely upon plasmonic effects and could utilize a wide variety of earth abundant metals. A light-harvesting cell (Photovoltaic or Thermal) coated with two different metallo-dielectric coatings can exploit metamaterials concepts. In both coatings the metal fraction decreases with increasing distance from the substrate. This results in a graded index coating that minimizes reflections over a broad wavelength range. The presence of nanoscale inclusions also induces beneficial light scattering and concentration effects, which are not found in layered dielectric antireflective coatings.

Coatings on solar cell substrates can improve electrical output and overall performance. The coating acts as a lens, absorber and/or an antireflective coating comprising one or more layers of dielectric materials including but not limited to: organic, metallic, nonmetallic, metalorganic, inorganic materials, metamaterials, microstructures or nanostructured metallo-dielectric films. Coatings may include structures that incorporate silicon, silica, air or gas inclusions.

Solar cell construction and installation includes many layers or stages of different materials intended to perform various functions. The correct engineering or design and positioning of nanostructured metallic coatings or materials could be used to enhance some or all of these functions for incremental improvements in solar cell performance or efficiency. Construction layers may incorporate metallic or metalized composite materials for collection and conduction, electrodes and contacts, semiconductor structures, pn junctions and semiconductor-metal interfaces, dielectric films, silicon and silica thin films, anti-reflection coatings, glass or other light transparent or TCO materials. Coatings deposited or deployed on or at external or internal surfaces or interfaces in various stages of construction could be tuned using nanoengineered materials. In an exemplary embodiment a nanostructured metallic coating may be engineered to capture, absorb and radiate or reflect photons in the infrared portion of the solar spectrum not addressed by the wavelength index or band gap of a particular solar cell. Such a coating could be deployed on collection, conduction or contact layer external or internal surfaces or interfaces. Photons would be radiated or reflected back into the cell to promote photo-excitation of electrons.

Many solar cells are assembled in modules or arrays and mounted, encapsulated or enclosed in glass or other light transparent or TCO materials for commercial deployment and installation. In some cases individual cells or groups of cells are encapsulated in glass or other light transparent or TCO materials. It is a feature of this invention that nanostructured or engineered anti-reflection coatings deposited on the external or internal interface and surface areas of the glass or other light transparent or TCO material used to encase the cell could reduce reflection and permit more light to reach the active layers of the cell and harvest energy.

It is a feature of this invention that the coatings described can be processed using established commercial deposition techniques. These may permit incorporation of the coatings and structures or methods described in tools, equipment, production lines or other fabrication systems whether automated or otherwise. Coating methods may include but are not limited to: chemical deposition in which a gas or fluid precursor undergoes a chemical change at a solid surface leaving a solid layer (e.g. plating, chemical solution deposition, sol-gel, chemical vapor deposition, plasma assisted chemical vapor deposition, plasmon assisted chemical vapor deposition, laser assisted chemical vapor deposition, laser assisted plasma chemical vapor deposition); physical vapor deposition in which mechanical or thermodynamic means produce a thin film or solid (e.g. thermal evaporator, microwave, sputtering, pulsed laser deposition, cathodic arc deposition, dipping, painting, printing, screen or ink-jet printing, spraying, annealing, lithography and photolithography using flexible or rigid masks, templates, or imprints of any sort); reactive sputtering in which a small amount of non-noble gas such as oxygen or nitrogen is mixed with a plasma-forming gas; molecular beam epitaxy in which slow streams of an element are directed at the substrate so material deposits one atomic layer at a time; and spontaneous or self-assembly induced by various means including nucleation, surface tension, strain, electrical or thermal activity.

A feature of this invention is to enable deposition or application of the coatings on various substrates. Coatings may be incorporated in or deposited on any substrate including solar cell or semiconductor devices or wafers composed of silicon, glass, metals, glass-metal-glass combinations, metal-glass-metal combinations, polymers or plastics, self-assembled monolayers or any other photovoltaic converter that converts light to energy, including mono or polysilicon, amorphous and microcrystalline Si, Copper Indium Gallium Selenide, Cadmium Telluride, organic or other solar cells. Coatings on a photovoltaic converter substrate will act as a light concentrating element or absorber. Coatings may also be deposited onto any material that has been deposited on a substrate including existing coatings such as antireflective or TCO coatings on solar cells. Coatings can be engineered to act as an antireflection coating based on layered metal or dielectric stacks.

A feature of this invention allows any metallic, organic, inorganic, nonmetallic, metalorganic, metamaterials, nanostructures, microstructures, nanopatterned structures or nanoengineered materials to be included in coatings. Examples include silicon dioxide, aluminum, zinc, nickel, indium, tin, copper, titanium dioxide, silver, gold, and other metals or metal oxides. Such materials may be used for local field enhancement, light scattering in waveguides, modes or paths for longer or redirected photons in a coating. Such materials may be used as antennas or receivers to capture light energy from solar or other sources. An exemplary embodiment may include structured nanoantennas contained in or deposited on any substrate, material or light-transparent material used to harvest electrical energy from optical, thermal or electromagnetic excitation.

In an exemplary embodiment, a reactive metal oxide sputtering process using silicon dioxide, silver, and titanium dioxide targets may be used to deposit films measuring a few hundred nanometers or less in thickness on commercial silicon photovoltaic solar cells. This process allows a non-optimized coating to be deposited on the anti-reflective silicon layer. Such coating may increase the performance efficiency of commercial solar cells. Coatings designed for and deposited directly on specific solar cells may further increase performance efficiencies.

In an exemplary embodiment it is possible to simulate and optimize the net overall absorption of a thin film Si solar cell over the entire solar spectrum. A general design strategy for the realization and optimization of broadband absorption enhancements in thin film solar cells using periodic, aperiodic or random arrays of metallic nanostructures is described herein. If light absorption could be improved in ultra-thin layers of active material it would lead directly to lower recombination currents, higher open circuit voltages, and higher conversion efficiencies. This could simultaneously take advantage of 1) the high near-fields surrounding the nanostructures close to their surface plasmon resonance frequency and 2) the effective coupling to waveguide modes supported the active layers through an optimization of the array properties. It is possible to use a simple model system consisting of a periodic array of metal particles on a thin spacer layer on a thin semiconductor film supported by a silica substrate to illustrate these concepts. Individual components of the cell structure are selected for the following reasons. These particles can effectively concentrate light in their vicinity at frequencies near their surface plasmon resonance. This resonance frequency critically depends on the particle geometry and its dielectric environment. It is well established that deep subwavelength particles cause relatively strong absorption and less scattering as compared to larger particles. No significant benefits from light scattering and trapping can thus be expected from very small particles. Studies have provided beneficial effects on the short circuit current for particles with characteristic sizes in the range from 50 nm-200 nm. Substantially larger particles behave like optical mirrors, reflecting most of the incident radiation back into free space. In contrast to near-field concentration effects, the lateral spacing of the particles governs the excitation of waveguide modes. The number of allowed waveguide modes and their dispersion is determined by the thickness of the semiconductor layer and this important parameter should be chosen carefully. Optimum coupling results when the reciprocal lattice vector of the particle-array (grating) is matched to the k-vector of a waveguide modes supported by the solar cell. The top oxide may serve as a spacer layer between the metal and the absorbing semiconductor layer. Other transparent materials, including a wide variety of oxides and organics may be used instead of SiO₂.

In a further exemplary embodiment it is possible to investigate the plasmon-enabled absorption enhancements due to the aforementioned effects by performing full-field electromagnetic simulations based on the finite-difference frequency-domain (FDFD) method. FDFD simulations enable the use of tabulated materials parameters and adaptive grid spacing. For the periodic arrays under study, it is possible to implement periodic boundary conditions and perfectly matched layer (PML) boundary conditions at the top and bottom of the simulation volume. This permits calculation of the absorption in the semiconductor slab for a normally incident plane wave. The absorption enhancements at various wavelengths can then be determined from the ratio of the absorbed light in the relevant semiconductor layer with and without metal particles.

In an exemplary embodiment in order to maximize the overall energy conversion efficiency under solar illumination, it is important to identify cell parameters that maximize the effects of near-field light concentration and trapping over a broad wavelength range. There are many parameters that impact the energy conversion efficiency of the cell. In complex cells with AR or TCO coatings, metallic back contacts, multi-junctions, etc. many parameters come into play. To explore such large parameter spaces blind optimization procedures cost significant computational power and time. Therefore the use of more physically intuitive strategies is desirable. By generating maps of the metal-induced absorption enhancement versus photon energy and reciprocal lattice constant, G=2π/P, the two key enhancement processes can conveniently be separated and studied. Each point in these maps represents a full-field simulation result with its corresponding illumination energy and period.

In a further exemplary embodiment test platforms can be used to assess the electronic and optical properties of plasmonic coatings or films in real device Si structures. To establish conductivity it is possible to deposit films on thin insulating silica substrates and perform conventional 4-point probe measurements. This allows for evaluation of light concentrating/trapping performance of plasmonic coatings by depositing them on silicon-on-insulator (SOI) wafers and taking photocurrent measurements. The thin Si layer in SOI will play the role of the active absorbing layer of the solar cell. SOI wafers are readily available. Photolithography can generate tens of thousands of test devices on a single wafer to serve as a rapid prototyping platform. Schottky contacts or lateral pn-junctions will be utilized for efficient carrier extraction. Each photolithography mask developed for such an exercise could support hundreds of dies, easily adding up to more than 10,000 devices on a single wafer. Each die can be cut and deposited with a different plasmonic coating. Photocurrent measurements can be performed as a function of wavelength using a white light source coupled to a monochromator. These measurements enable assessment of the spectral dependence of the photocurrent enhancement.

The various features, methods, means or structures of the invention described herein could be expressed in any combination in any or all of the following or any other architectures, form factors, materials or combination of materials including:

A metallic

A nonmetallic

An organic

An inorganic

A metal organic

A metal organic compound

An organometallic

A metal oxide

A transparent oxide

A transparent conducting oxide

An oxide

A metal oxide film

A metal oxide composite film

A silicon

A silica

A silicate

A ceramic

A composite

A compound

A polymer

A plastic

An organic composite thin film

An organic composite coating

An inorganic composite thin film

An inorganic composite coating

An organic and inorganic composite thin film

An organic and inorganic composite coating

A thin film crystal lattice nanostructure

An active photonic matrix

A flexible multi-dimensional film, screen or membrane

A microprocessor

A MEMS or NEMS device

A microfluidic or nanofluidic chip

A single nanowire, nanotube or nanofiber

A bundle of nanowires, nanotubes or nanofibers

A cluster, array or lattice of nanowires, nanotubes or nanofibers

A single optical fiber

A bundle of optical fibers

A cluster, array or lattice of optical fibers

A cluster, array or lattice of nanoparticles

Designed or shaped single nanoparticles at varying length scales

Nanomolecular structures

Nanowires, dots, rods, particles, tubes, sphere, films or like materials in any combination

Nanoparticles suspended in various liquids or solutions

Nanoparticles in powder form

Nanoparticles in the form of pellets, liquid, gas, plasma or otherwise

Nanostructures, nanoreactors, microstructures, microreactors, macrostructures or other devices

Combinations of nanoparticles or nanostructures in any of the forms described or any other form

Nanopatterned materials

Nanopatterned nanomaterials

Nanopatterned micro materials

Micropatterned metallic materials

Microstructured metallic materials

Metallic micro cavity structures

Metal dielectric material

Metal dielectric metal materials

Autonomous self-assembled or self-assembling structure of any kind

Combination of dielectric metal materials or metal dielectric metal materials

A semiconductor

Semiconductor materials including, SOI, germanium, gallium arsenide, quartz, glass, inductive, conductive or insulation materials, integrated circuits, wafers, or microchips

An insulator

A conductor

A paint, coating, powder or film in any form containing any of the materials identified herein or any other materials in any combination

Combinations of nanoparticles or nanostructures in any of the forms described or any other form

All or any of the materials or forms described herein may be designed, used or deployed on or in flexible, elastic, conformable structures. Said structures or surface areas may be expanded or enlarged by the use of advanced non-planar, non-linear geometric and spatial configurations.

In any embodiment or description contained herein the method of enabling the various functions, tasks or features contained in this invention includes performing the operation of some or all of the steps outlined in conjunction with the preferred processes or devices. This description of the operation and steps performed is not intended to be exhaustive or complete or to exclude the performance or operation of any additional steps or the performance or operation of any such steps or the steps in any different sequence or order.

The foregoing means and methods are described as exemplary embodiments of the invention. Those examples are intended to demonstrate that any of the aforementioned steps, processes or devices may be used alone or in conjunction with any other in the sequence described or in any other sequence.

It is also understood that the examples and implementations described herein are for illustrative purposes only and that various modifications or changes in light thereof will be suggested to persons skilled in the art and are to be included within the spirit and purview of this application.

1. A method of combining transparent nanopatterned metallic structures or thin-film as contacts or electrodes to create organic or inorganic photovoltaic subcells or multijunction stacks:
where at least subcells or multijunction stacks can be spectrally or optically tuned,
where at least absorption properties may be enhanced through the conductivity of transparent metal contacts,
where at least the resulting structures can be engineered to incorporate all the features and functions required to operate independently as a solar cell and may be deposited on or combined with any substrate.

2. The method of claim 1 where at least nanostructured metallic coatings on solar cell substrates can improve electrical output and overall performance:
where at least the coating acts as a light concentrating element, absorber and/or an antireflective coating comprising one or more layers of dielectric materials including but not limited to: organic, metallic, nonmetallic, metalorganic, inorganic materials, metamaterials, microstructures or nanostructured metallo-dielectric films,
where at least coatings may include structures that incorporate silicon, silica, air or gas inclusions.

3. The method of claim 1 where at least solar cell or module construction and installation includes many layers or stages of different materials intended to perform various functions:
where at least the correct engineering or design and positioning of nanostructured metallic coatings or materials could be used to enhance some or all of these functions for incremental improvements in solar cell performance or efficiency,
where at least construction layers may incorporate metallic or metalized composite materials for collection and conduction, electrodes and contacts, semiconductor structures, pn junctions, semiconductor-metal interfaces, dielectric films, silicon and silica thin films, anti-reflection coatings, glass or other light transparent or TCO materials,
where at least coatings deposited or deployed on or at external or internal surfaces or interfaces in various stages of construction could be tuned using nanoengineered materials,
where at least a coating may be engineered to capture, absorb and radiate or reflect photons in the infrared portion of the solar spectrum not addressed by the wavelength index or band gap of a particular solar cell,
where at least such a coating could be deployed on collection, conduction or contact layer external or internal surfaces or interfaces,
where at least photons would be radiated or reflected back into the cell to promote photo-excitation of electrons.

4. The method of claim 1 in which the coatings described can be processed using either of commercial or customized deposition techniques, tools and equipment where at least coating methods may include: chemical deposition in which a gas or fluid precursor undergoes a chemical change at a solid surface leaving a solid layer (e.g. plating, sol-gel, chemical solution deposition, chemical vapor deposition, plasma assisted chemical vapor deposition, plasmon assisted chemical vapor deposition, laser assisted chemical vapor deposition, laser assisted plasma chemical vapor deposition); physical vapor deposition in which mechanical or thermodynamic means produce a thin film or solid (e.g. thermal evaporator, microwave, sputtering, pulsed laser deposition, cathodic arc deposition, dipping, painting, printing, screen or ink-jet printing, spraying, annealing, lithography and photolithography using flexible or rigid masks, templates, or imprints of any sort); reactive sputtering in which a small amount of non-noble gas such as oxygen or nitrogen is mixed with a plasma-forming gas; molecular beam epitaxy in which slow streams of an element are directed at the substrate so material deposits one atomic layer at a time; and spontaneous or self-assembly induced by various means including nucleation, surface tension, strain, electrical or thermal activity.

5. The method of claim 1 where at least deposition or application of the coatings described on various substrates is enabled:
where at least coatings may be incorporated in or deposited on any substrate including solar cell or semiconductor devices or wafers composed of silicon, glass, metals, glass-metal-glass combinations, metal-glass-metal combinations, polymers or plastics, self-assembled monolayers or any other photovoltaic converter that converts light to energy, including mono or polysilicon, amorphous, and microcrystalline Si, Copper Indium Gallium Selenide, Cadmium Telluride, organic or other solar cells:
where at least coatings on a photovoltaic converter substrate will act as a light concentrating element or absorber,
where at least coatings may also be deposited onto any material that has been deposited on a substrate including existing coatings such as antireflective coatings on solar cells,
where at least coatings can be engineered to act as an antireflection coating based on layered metal or dielectric stacks.

6. The method of claim 1 which at least allows any metallic, organic, inorganic, nonmetallic, metalloorganic, metamaterials, nanostructures, microstructures, nanopatterned structures or nanoengineered materials to be included in coatings:
where at least silicon dioxide, aluminum, zinc, nickel, indium, tin, copper, titanium titanium dioxide, silver, gold, and other metals or metal oxides may be included in coatings,
where at least such materials may be used for local field enhancement, light scattering in waveguides, modes or paths for longer or redirected photons in a coating,
where at least such materials may be used as antennas or receivers to capture light energy from solar or other sources,
where at least structured nanoantennas contained in or deposited on any substrate, material or light-transparent material may be used to harvest electrical energy from optical, thermal or electromagnetic excitation.

7. A method of claim 1 where at least a reactive metal oxide sputtering process using silicon dioxide, silver, and titanium dioxide targets may be used to deposit films measuring nanometers in thickness on commercial silicon photovoltaic solar cells:
where at least this process allows a non-optimized coating to be deposited on the anti-reflective silicon layer,
where at least such coating may increase the performance efficiency of commercial solar cells,
where at least such coatings designed for and deposited directly on specific solar cells may further increase performance efficiencies.

8. The method of claim 1 which contains at least any or all of the following or any other architectures, form factors, materials or combination of materials including a metallic; a nonmetallic; an organic, an inorganic; a metal organic; a metal organic compound; an organometallic; a metal oxide, a transparent oxide, a transparent conducting, an oxide; a metal oxide film; a metal oxide composite film; a silicon; a silica; a silicate; a ceramic; a composite; a compound; a polymer; a plastic; an organic composite thin film; an organic composite coating; an inorganic composite thin film; an inorganic composite coating; an organic and inorganic composite thin film; an organic and inorganic composite coating; a thin film crystal lattice nanostructure; an active photonic matrix; a flexible multi-dimensional film; screen or membrane; a microprocessor; a MEMS or NEMS device; a microfluidic or nanofluidic chip; a single nanowire, nanotube or nanofiber; a bundle of nanowires, nanotubes or nanofibers; a cluster, array or lattice of nanowires, nanotubes or nanofibers; a single optical fiber; a bundle of optical fibers; a cluster, array or lattice of optical fibers; a cluster, array or lattice of nanoparticles; designed or shaped single nanoparticles at varying length scales; nanomolecular structures; nanowires, dots, rods, particles, tubes, sphere, films or like materials in any combination; nanoparticles suspended in various liquids or solutions; nanoparticles in powder form; nanoparticles in the form of pellets, liquid, gas, plasma or otherwise; nanostructures, nanoreactors, microstructures, microreactors, macrostructures or other devices; combinations of nanoparticles or nanostructures in any of the forms described or any other form; nanopatterned materials; nanopatterned nanomaterials; nanopatterned micro materials; micropatterned metallic materials; microstructured metallic materials; metallic micro cavity structures; metal dielectric material; metal dielectric metal materials; autonomous self-assembled or self-assembling structure of any kind; combination of dielectric metal materials or metal dielectric metal materials; a semiconductor; semiconductor materials including SOI, gallium arsenide, germanium, quartz, glass, inductive, conductive or insulation materials, integrated circuits, wafers, or microchips; an insulator; a conductor; a paint, coating, powder or film in any form containing any of the materials identified herein or any other materials in any combination; combinations of nanoparticles or nanostructures in any of the forms described or any other form; all or any of the materials or forms described herein may be designed, used or deployed on or in flexible, elastic, conformable structures; said structures or surface areas may be expanded or enlarged by the use of advanced non-planar, non-linear geometric and spatial configurations.

9. A method of using nanostructured metallo-dielectric coatings to boost the efficiency of solar harvesting devices (Photovoltaic and Thermal):
where at least coatings effectively reduce back-reflection of light over a broad wavelength range,
where at least coatings promote forward scattering of light into oblique directions that more strongly interact with the active medium such as waveguide modes in thin solar cells,
where at least coatings enable light concentration in those regions of the cell where light absorption most efficiently produces current, e.g. in the pn-junction or near a donor acceptor interface,
where at least a cell or substrate (Photovoltaic or Thermal) is coated with a metallo-dielectric coating where the layer consists of dielectric elements and metallic nanostructures and the total thickness and composition of the coating is optimized to reduce back-reflection of light over a broad wavelength range,
where at least subwavelength metallic nanostructures can enable local light concentration and scattering into oblique angles for coupling into waveguide modes.

10. A method of claim 9 where at least many solar cells are assembled in modules or arrays and mounted, encapsulated or enclosed in glass or other light transparent or TCO materials for commercial deployment and installation:
where at least in some cases individual cells or groups of cells are encapsulated in glass or other light transparent or TCO materials,
where at least nanostructured or engineered anti-reflection coatings deposited on the external or internal interface and surface areas of the glass or other light transparent or TCO material used to encase the cell could reduce the reflection and permit more light to reach the active layers of the cell and harvest energy.

11. A method of claim 9 using layers which consist of dielectric films with a monolayer of metallic particles embedded in them:
where at least the particle shape, size, choice of metal, spacing between particles and distance to the substrate should be optimized to enable a specific goal, e.g. strong near-field enhancement or light scattering into oblique angles,
where at least the total thickness of the metallo-dielectric stack will be chosen to minimize back-reflection (AR coating effect) and increase the coupling into the cell,
where at least metals exhibiting strong plasmonic resonances may be advantageous for these types of coatings.

12. A method of claim 9 where coating designs may employ concepts and metamaterials comprised of deep subwavelength building blocks to enable the ultimate control over the flow of light:
where at least metallo-dielectric coatings consisting of deep subwavelength metallic nanostructures in a dielectric matrix possess an effective index that can be locally engineered through a proper choice and placement of metallic inclusions,
where at least these metamaterial coatings can be designed to act as superior broadband anti-reflection coating as well as a light scattering and light concentration layers,
where at least these types of coatings can be engineered to produce a desired index variation above the cell by altering the metal fraction in the coating as a function of the distance from the substrate,
where at least such coatings can be designed to act as a multilayer antireflective coating or so-called “moth eye” structure exhibiting a substantial reduction in light reflection over single layer antireflection coatings,
where at least a moth eye structure could be used as it is a highly non-reflective with orderly nanostructured surface variations to allow absorption rather than reflection of incoming light,
where at least such coatings could generate higher cell efficiencies when compared to a cell with a multilayer dielectric anti-reflective coating due to enhanced light concentration and scattering effects,
where at least the operation of a metamaterials coating does not rely upon plasmonic effects and could utilize a wide variety of earth abundant metals,
where at least a light-harvesting cell (Photovoltaic or Thermal) coated with two different metallo-dielectric coatings can exploit metamaterials concepts,
where at least in both coatings the metal fraction decreases with increasing distance from the substrate,
where at least a graded index coating results that minimizes reflections over a broad wavelength range,
where at least the presence of nanoscale inclusions also induces beneficial light scattering and concentration effects, which are not found in layered dielectric antireflective coatings.

13. A method of simulation, optimization and design for the net overall absorption of a thin film solar cell over the entire solar spectrum:
where at least light absorption could be improved in ultra-thin layers of active material it would lead directly to lower recombination currents, higher open circuit voltages, and higher conversion efficiencies,
where at least this could simultaneously take advantage of the high near-fields surrounding the nanostructures close to their surface plasmon resonance frequency and the effective coupling to waveguide modes supported by the active layers through an optimization of the array properties,
where at least it is possible to use a simple model system consisting of a periodic array of metal particles on a thin spacer layer on a thin semiconductor film supported by a substrate to illustrate these concepts,
where at least individual components of the cell structure are selected,
where at least the metal particle geometry can effectively concentrate light in its vicinity at frequencies near its surface plasmon resonance,
where at least resonance frequency critically depends on the particle geometry and its dielectric environment.

14. A method of claim 13 for a general design strategy for the realization and optimization of broadband absorption enhancements in thin film solar cells using 2-dimensional and 3 dimensional periodic, aperiodic or random arrays of metallic nanostructures.

15. A method of claim 13 to maximize the overall energy conversion efficiency under solar illumination by identifying cell parameters that maximize the effects of near-field light concentration and trapping over a broad wavelength range:
where at least there are many parameters that impact the energy conversion efficiency of the cell,
where at least in more complex cells many parameters come into play;
where at least to explore such large parameter spaces the use of more physically intuitive strategies is desirable,
Where at least by generating maps of the metal-induced absorption enhancement versus photon energy and reciprocal lattice constant, G=2π/P, the two key enhancement processes can be separated, studied or optimized.

16. A method of claim 13 where a test platform can be used to assess the electronic and optical properties of plasmonic coatings or films in real device structures:
where at least it is possible to deposit films and establish conductivity on thin insulating substrates and perform conventional 4-point probe measurements,
where at least the evaluation of light concentrating/trapping performance of plasmonic coatings can be obtained by depositing them on silicon-on-insulator (SOI) wafers and taking photocurrent measurements,
where at least photolithography can generate tens of thousands of test devices on a single wafer to serve as a rapid prototyping platform.
where at least Schottky contacts or lateral pn-junctions may utilized for efficient carrier extraction,
where at least photocurrent measurements may be performed as a function of wavelength using a white light source coupled to a monochromator,
where at least these measurements may enable assessment of the spectral dependence of the photocurrent enhancement.
